(19) United States
(12) Patent Application Publication
(10) Pub. No.: US 2026/0090042 A1
(43) Pub. Date: Mar. 26, 2026

(54) SEMICONDUCTOR DEVICE AND METHOD FOR FORMING THE SAME

(71) Applicant: UNITED MICROELECTRONICS CORP., Hsin-Chu City (TW)

(72) Inventors: Yu-Teng Tseng, Hsinchu City (TW); Huai-Jin Hsing, Taichung City (TW); Tzu-Wei Liao, Pingtung County (TW); Chu-Chun Chang, Kaohsiung City (TW); Chi-Hsuan Tang, Kaohsiung City (TW); Kuang-Hsiu Chen, Tainan City (TW); Shi-Xiong Lin, Yilan County (TW); Kuo-Yuh Yang, Hsinchu County (TW); Purakh Raj Verma, Singapore (SG)

(73) Assignee: UNITED MICROELECTRONICS CORP., Hsin-Chu City (TW)

(21) Appl. No.: 18/918,041

(22) Filed: Oct. 16, 2024

(30) Foreign Application Priority Data
Sep. 24, 2024 (TW) 113136166

(51) Int. Cl. H01L 29/06; H01L 21/762

(52) U.S. Cl. CPC H10D 62/126; H10P 90/1906; H10W 10/021; H10W 10/061; H10W 10/181; H10W 10/20

(57) ABSTRACT

A semiconductor device includes a substrate having an insulating layer and a device layer disposed on the insulating layer, wherein the device layer includes an active region, a plurality of gate structures arranged parallel to each other on the active region, a recess formed in the active region located between adjacent two of the gate structures and extending through the device layer, an epitaxial layer filling the recess, and an air gap between a bottom surface of the epitaxial layer and a top surface of the insulating layer.

### BACKGROUND OF THE INVENTION

### 1. Field of the Invention

The present invention relates to a semiconductor device and a method for forming the same. More particularly, the present invention relates to a semiconductor device formed on a SOI substrate and a method for forming the same.

### 2. Description of the Prior Art

RF-SOI is a semiconductor technology platform specifically designed for radio frequency devices, including low noise amplifiers, switches, and antenna tuners. An RF-SOI device is constructed on a silicon-on-insulator (SOI) substrate, which may reduce leakage and parasitic effects associated with the substrate. As a result, it is possible to achieve higher linearity and lower power consumption during high-frequency operation and rapid power switching.

The quality factor (figure of merit, FoM) of an RF device is inversely proportional to the product of on-resistance (Rₒₙ) and off-capacitance (C_{off}). The smaller the values of Rₒₙ and C_{off}, the higher quality factor for RF devices. Consequently, reducing C_{off} of RF devices has become an important research topic in the field.

### SUMMARY OF THE INVENTION

One embodiment of the present invention provides a semiconductor device that includes a substrate with an insulating layer and a device layer disposed on the insulating layer. The device layer includes an active region, a plurality of gate structures arranged parallel to each other on the active region, a recess in the active region located between adjacent two of the gate structures and penetrating through the device layer, an epitaxial layer in the recess, and an air gap between a bottom surface of the epitaxial layer and a top surface of the insulating layer.

Another embodiment of the present invention provides a method for forming a semiconductor device including the steps of providing a substrate comprising an insulating layer and a device layer disposed on the insulating layer, wherein the device layer comprises an active region, forming a plurality of gate structures arranged parallel to each other on the active region, forming a recess in the active region and between adjacent two of the gate structures, wherein the recess penetrates through the device layer, exposing a top surface of the insulating layer, and forming an epitaxial layer in the recess and an air gap between a bottom surface of the epitaxial layer and a top surface of the insulating layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 9 are schematic drawings illustrating the steps for forming a semiconductor device according to an embodiment of the present invention. FIG. 1, FIG. 3, FIG. 7 and FIG. 9 are top views. FIG. 2, FIG. 4, FIG. 5, FIG. 6 and FIG. 8 are cross-sectional views along the line AA′ in the top views.

FIG. 10 is a schematic drawing illustrating a cross-sectional view of a semiconductor device according to an embodiment of the present invention.

### DETAILED DESCRIPTION

To facilitate understanding of the present invention to those of ordinary skill in the art, several exemplary embodiments will be detailed below, accompanied by references to the numbered elements in the drawings to elaborate the contents and effects to be achieved.

The drawings of the present invention are schematic and not drawn to scale. Some components may be enlarged for clarity. The same reference signs are generally used to refer to corresponding or similar features in modified and different embodiments. The spatial terms mentioned in the specification, such as “below”, “low”, “down”, “above”, “on top”, “over”, “top”, “bottom”, or the like, are understood by those skilled in the art to describe the relative spatial relationships of one component or feature to another (or multiple) components or features in the drawings. Any rotation (such as rotating 90 degrees or other orientations) will still conform to the spatial descriptions in the specification. Reference directions, such as a first direction X, a second direction Y and a third direction Z are illustrated in the drawings to facilitate spatial-related descriptions, wherein the first direction X and the second direction Y are perpendicular to each other, and the third direction Z is perpendicular to the plane defined by the first direction X and the second direction Y.

In this specification, a “substrate” refers to any structure with an exposed surface on which materials may be deposited according to the embodiments of the present invention for the manufacture of integrated circuit structures. A “substrate” also refers to a semiconductor structure that includes material layers formed thereon during the manufacturing process. When a component or layer is described as being “on another component or layer” or “connected to another component or layer,” it may be either directly on or directly connected to another component or layer, or it may be indirectly on or indirectly connected to another component or layer, with other components or layers present in between. On the contrary, when a component is described as being “directly on another component or layer” or “directly connected to another component or layer,” there are no intervening components or layers between them. The terms “equal”, “equivalent”, “identical”, or “substantially” are generally interpreted as being within 20% of a given value or range, or as being within 10%, 5%, 3%, 2%, 1%, or 0.5% of a specified value or range. It is important to note that there may be a certain degree of error between any two values or directions used for comparison.

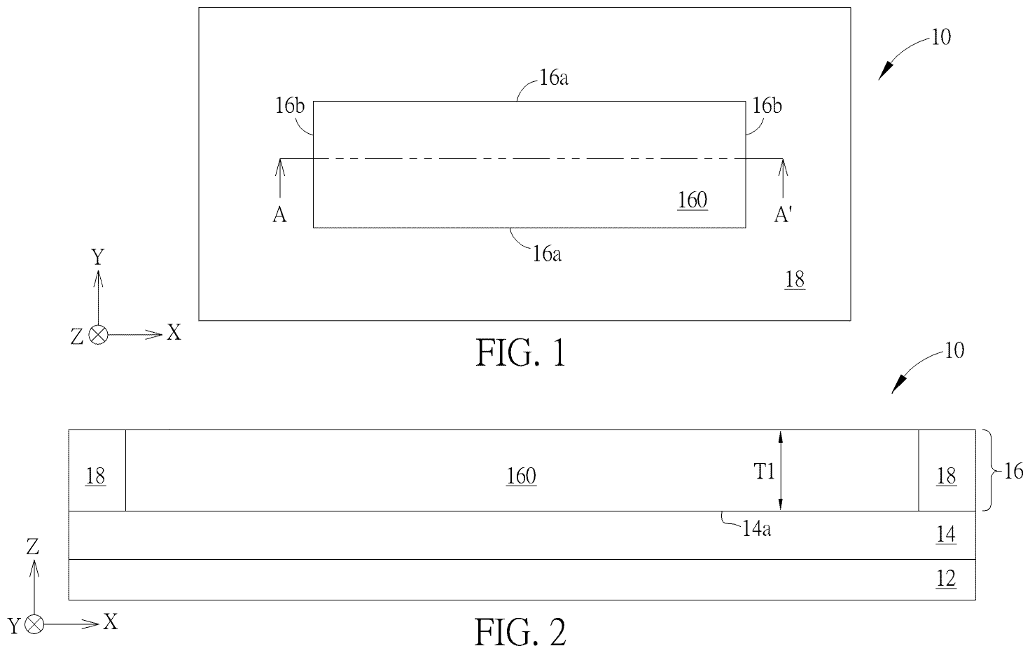

Please refer to FIG. 1 and FIG. 2. A substrate 10 is provided, which may be a partially depleted silicon-on-insulator (PDSOI) substrate or a full depleted silicon-on-insulator (FDSOI) substrate, but is not limited thereto. The substrate 10 includes a base layer 12, an insulating layer 14 disposed on the base layer 12, and a device layer 16 disposed on the insulating layer 14. The top surfaces of the base layer 12, the insulating layer 14, and the device layer 16 are coplanar with the plane defined by the first direction X and the second direction Y. The base layer 12 may be a high-resistivity silicon (Si) substrate. The insulating layer 14 is made of a dielectric material, including silicon dioxide (SiO2) or silicon nitride (SiN). The device layer 16 includes semiconductor materials, including silicon (Si), germanium (Ge), silicon-germanium (SiGe), silicon-germanium-carbon (SiGe:C), silicon carbide (SiC), or a combination thereof, but is not limited thereto. The thickness T1 of the device layer 16 is preferably between 500 Å and 1450 Å, but is not limited thereto. An isolation structure 18 is formed in the device layer 16 to define at least an active region 160 in the device layer 16. The isolation structure 18 may be a shallow trench isolation (STI) structure or a local oxidation of silicon (LOCOS), but is not limited thereto. As shown in FIG. 2, the active region 160 is approximately rectangular in shape, with two first edges 16a extending along the first direction X and two second edges 16b extending along the second direction Y. The isolation structure 18 has a depth that extends through the entire thickness of the device layer 16. The bottom surface of the isolation structure 18 may be flush with or slightly lower than the top surface 14a of the insulating layer 14.

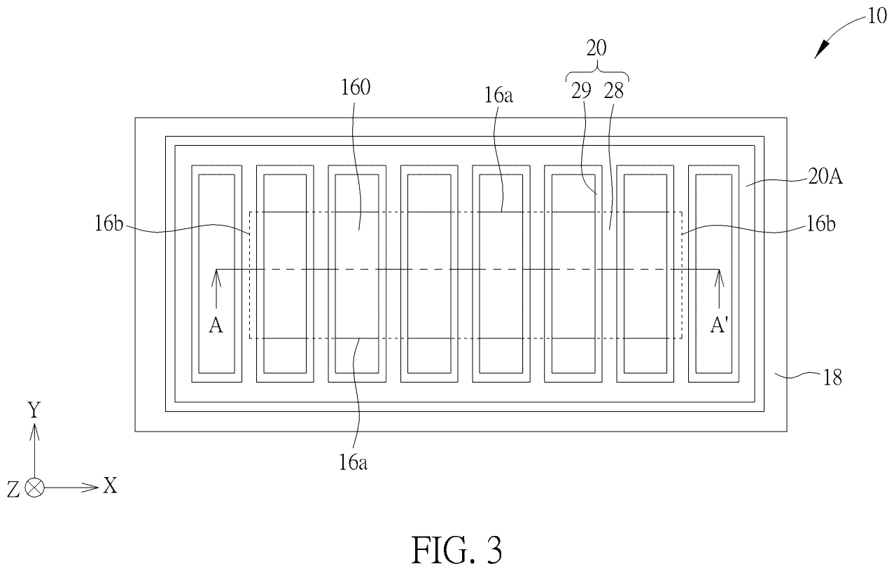

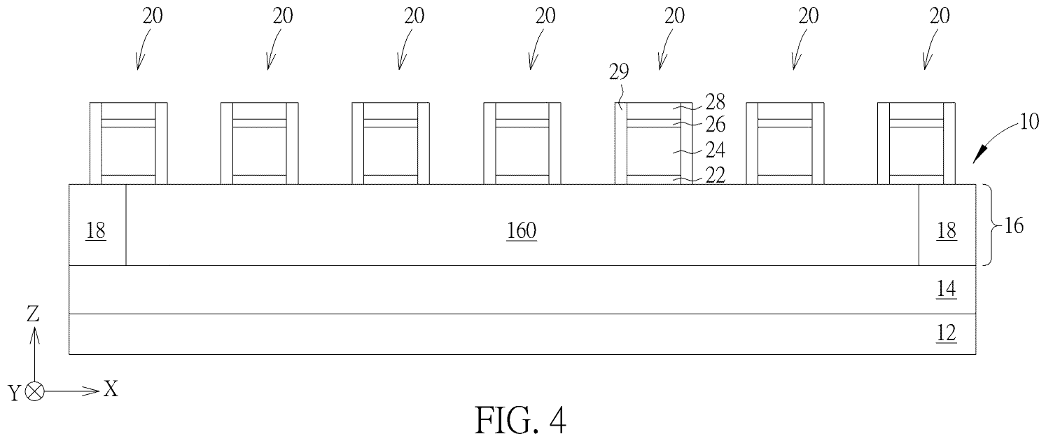

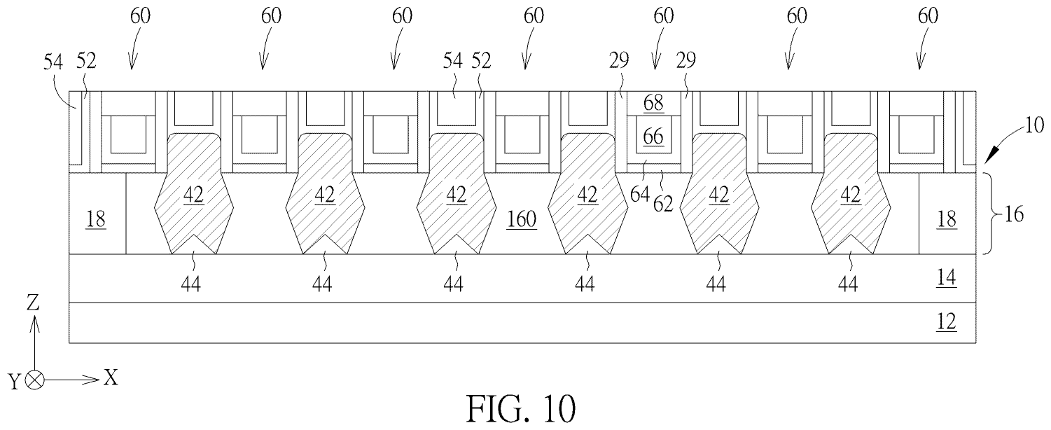

Please refer to FIG. 3 and FIG. 4. Subsequently, a plurality of gate structures 20 are formed on the device layer 16. The gate structures 20 extend along the second direction Y across the device region 160, and are arranged parallel to each other along the first direction X. Specifically, each of the gate structures 20 includes a gate stack and a spacer 29 disposed on the sidewall of the gate stack. The gate stack may include, from bottom to top, a gate dielectric layer 22, a gate conductive layer 24, an insulating layer 26, and a cap layer 28. According to an embodiment, the material of the gate dielectric layer 22 may include silicon dioxide (SiO₂), the material of the gate conductive layer 24 may include poly silicon, the material of the insulating layer 26 may include silicon dioxide (SiO₂), the material of the cap layer 28 may include silicon dioxide (SiO₂), but are not limited thereto. The spacer 29 may include a single-layer or multi-layer structure made of silicon dioxide (SiO₂), silicon nitride (SiN), silicon oxynitride (SiON), silicon carbonitride (SiCN), or a combination thereof, but is not limited thereto. In some embodiments, the gate structures 20 are dummy gate structures and will be replaced by metal gate structure 60 (referring to FIG. 10) in later process. In some embodiments, a closed ring-shaped outer structure 20A may be formed on the substrate 10, arranged on the isolation structure 18 and surrounding the gate structures 20. The outer structure 20A and the gate structures 20 are physically connected. The outer structure 20A and the gate structures 20 are made in one-piece and have same materials. In the top view shown in FIG. 3, the outer structure 20A and the gate structures 20 form a grid-like structure.

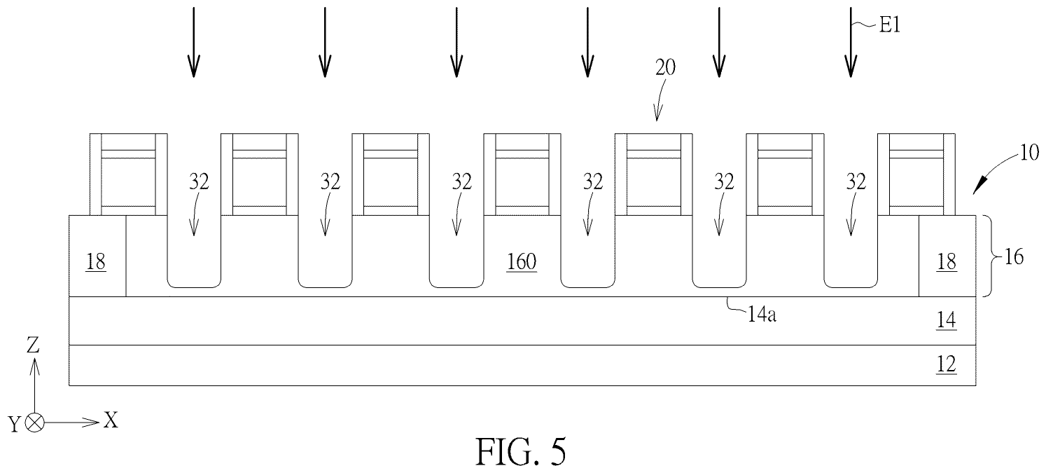

Please refer to FIG. 5. Subsequently, using the gate structures 20 and the spacers 29 as an etching mask, a dry etching process E1 is carried out to etch and remove the exposed portions of the device layer 16 between the gate structures 20, thereby forming first recesses 32 in the device layer 16 between the gate structures 20. The dry etching process E1 may be a reactive ion etching (RIE) process employing chlorine (Cl₂), hydrogen bromide (HBr), sulfur hexafluoride (SF₆), or a combination of the above compounds as etchant to etch the device layer 16. The first recesses 32 respectively have a U-shaped cross-sectional shape, with the bottoms not penetrating through the device layer 16. The depths of the first recesses 32 are preferably between 70% and 90% of the thickness of the device layer 16.

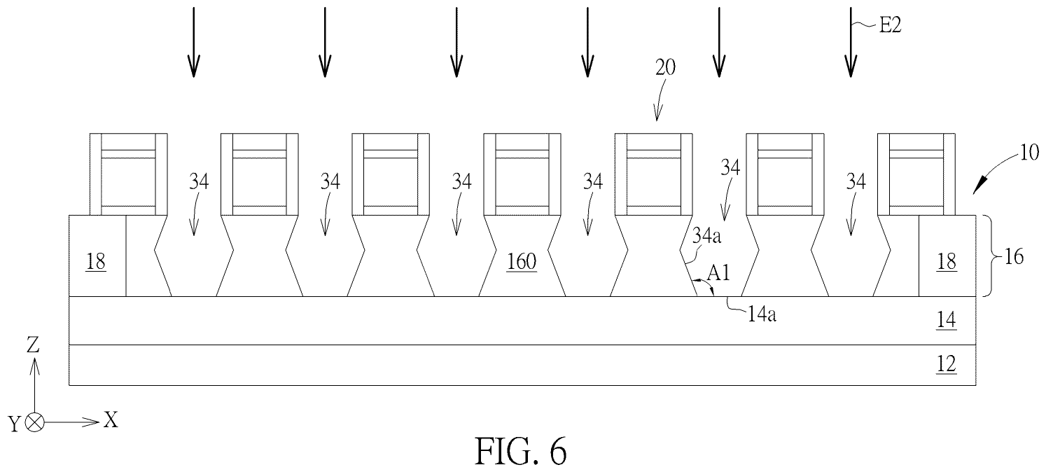

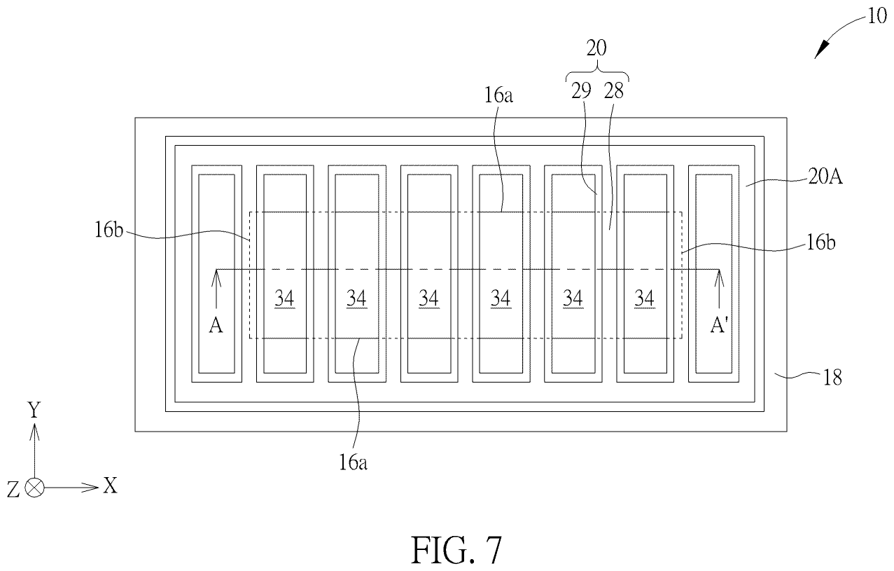

Please refer to FIG. 6 and FIG. 7. Subsequently, a wet etching process E2 is performed to etch the exposed portions of the device layer 16 in the first recesses 32 until the top surface 14a of the insulating layer 14 is exposed from the first recesses 32, thereby expanding the first recesses 32 anisotropically, forming the second recesses 34. In a preferred embodiment, the wet etching process E2 employs alkaline etchants such as potassium hydroxide (KOH), sodium hydroxide (NaOH), hydrazine (N₂H₄), cesium hydroxide (CsOH), tetramethylammonium hydroxide (TMAH), ethylenediamine-phenol (EDP), or a combination thereof, which have different etching rates on different crystal planes of the material of the device layer 16, such as silicon (Si). For example, the wet etching process E2 may have a slower etching rate on the <111> crystal plane compared to the <100> or <110> crystal planes of the device layer 16, thereby etching the sidewalls 34a of the recesses 34 into specific crystal planes. Consequently the recesses 34 respectively have a polygonal cross-sectional shape, which may include pentagonal, hexagonal, octagonal, or diamond-shaped cross-sectional shape, but are not limited thereto. In the illustrated embodiment shown in FIG. 6, the second recesses 34 are diamond-shaped, having wedge-shaped sidewalls 34a that form an obtuse angle A1 with the top surface 14a of the insulating layer 14. According to an embodiment of the present invention, the obtuse angle A1 is between 120 degrees and 130 degrees. In the top view depicted in FIG. 7, the second recesses 34 are respectively situated between the gate structures 20, extending along the second direction Y, and are parallel to the gate structures 20. The two ends of each of the second recesses 34 are flush with the first edges 16a of the active region 160.

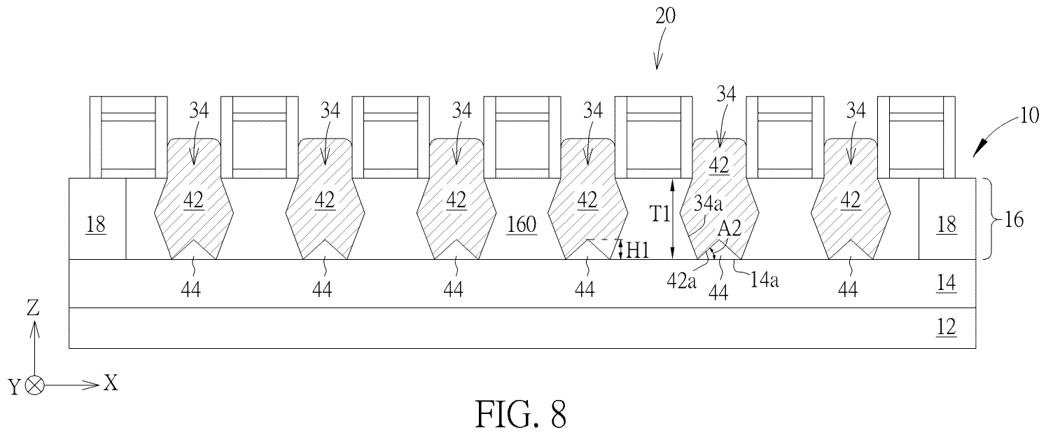

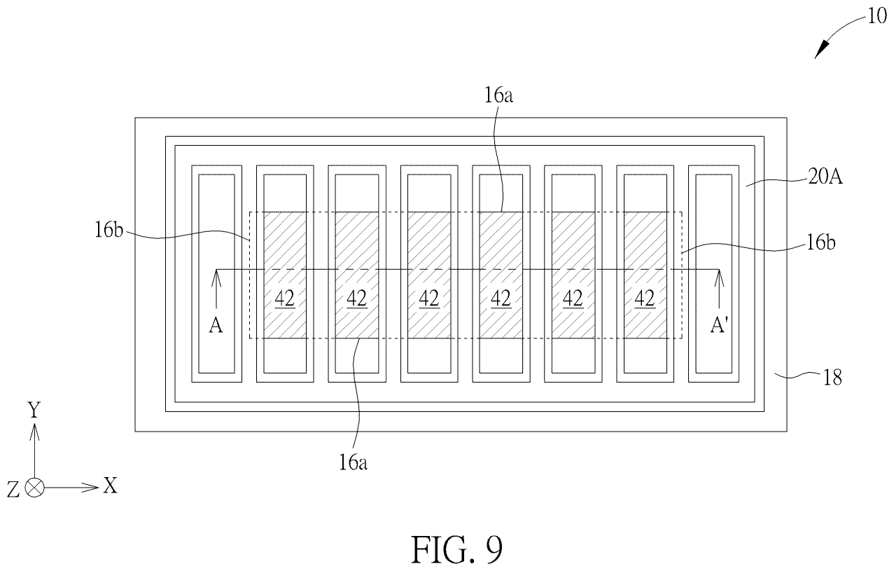

Please refer to FIG. 8 and FIG. 9. Subsequently, an epitaxial growth process is conducted to form epitaxial layers 42 filling the recesses 34. The materials of the epitaxial layers 42 include semiconductor materials, such as silicon (Si), germanium (Ge), silicon-germanium (SiGe), silicon-germanium-carbon (SiGe:C), silicon carbide (SiC), germanium-tin (GeSn), or silicon-germanium-tin (SiGeSn), or a combination thereof, but is not limited thereto. The epitaxial layers 42 may optionally include conductive dopants, such as phosphorus (P), arsenic (As), antimony (Sb), boron (B), boron difluoride (BF2), or a combination thereof, but is not limited thereto. It is preferable to continue the epitaxial growth process until the top surfaces of the epitaxial layers 42 are elevated above the surface of the active region 160 to form raised source/drain (RSD) regions for the semiconductor device.

It is noteworthy that, in each second recess 34, the epitaxial layer 42 grows selectively on the sidewall 34a of the second recess 34 and does not grow on the top surface 14a of the insulating layer 14, so that the portion of the epitaxial layer 42 at the junction between the sidewall 34a and the top surface 14a grows along a relatively stable crystal plane (facet), such as the <311> or <111> crystal plane, until it comes into contact with the portion of the epitaxial layer 42 that grows from the opposite sidewall 34a along the crystal plane, thereby forming an air gap 44 between the bottom surface of the epitaxial layer 42 and the top surface 14a of the insulating layer 14. At this point, the fabrication of the semiconductor device in this embodiment is complete.

Please refer to FIG. 8 and FIG. 9. The semiconductor device provided by the present invention includes a substrate 10 including an insulating layer 14 and a device layer 16 disposed on the insulating layer 14. An isolation structure 18 is formed in the device layer 16 to define an active region 160 in the device layer 16. A plurality of gate structures 20 are arranged parallel to each other on the active region 160. A plurality of recesses 34 (the second recesses) are formed in active region 160 between adjacent gate structures 20 and penetrating through the entire thickness of the device layer 16. A plurality of epitaxial layers 42 are formed in the recesses 34. An air gap 44 is formed between the bottom surface 42a of each epitaxial layer 42 and the top surface 14a of the insulating layer 14, where the bottom surface 42a of the epitaxial layer 42 forms the top surface of the air gap 44, and the top surface 14a of the insulating layer 14 forms the bottom surface of the air gap 44. In some embodiments of the present invention, the bottom surface 42a of the epitaxial layer 42 has a wedge cross-sectional shape and forms an acute angle A2 with the bottom surface 14a of the insulating layer 14. The angle of the acute angle A2 is determined by the crystal plane (facet) of the epitaxial layer 42. In some embodiments of the present invention, the acute angle A2 ranges from 20 degrees to 60 degrees. The air gap 44 has a triangular cross-sectional shape. Preferably, the height H1 of the air gap 44 (or the distance from the apex of the wedge-shaped bottom surface 42a to the top surface 14a of the insulating layer) is approximately between 20% and 25% of the thickness of the device layer 16. According to an embodiment of the present invention, the bottom surface of the air gap 44 is aligned with the bottom surface of the isolation structure 18 along the top surface 14a of the insulating layer 14. As shown in the top view illustrated in FIG. 9, the epitaxial layers 42 are respectively located between the gate structures 20, extending along the second direction Y, and are parallel to the gate structures 20. The two ends of each of the epitaxial layers 42 are flush with the first edges 16a of the active region 160. The air gaps 44 directly beneath the epitaxial layers 42 also extend approximately along the second direction Y. In some embodiments of the present invention, the two ends of each of the air gaps 44 may be flush with the first edges 16a of the active region 160. The epitaxial layers 42 are the source/drain regions of the semiconductor device. By forming the air gaps 44 between the epitaxial layers 42 and the insulating layer 14, the off capacitance (C_{off}) of the semiconductor device may be effectively reduced, and the device performance may be enhanced.

Please refer to FIG. 10. In some embodiments of the present invention, the gate structures 20 may be replaced by metal gate structure 60 through a replacement metal gate (RMG) process. For example, after forming the epitaxial layers 42 as illustrated in FIG. 8, a contact etching stop layer 52 and a dielectric layer 54 are sequentially formed on the substrate 10, covering the isolation structure 18, the gate structures 20, and the epitaxial layers 42. A chemical mechanical polishing process is then carried out to remove a portion of the dielectric layer 54 and the contact etching stop layer 52 until the cap layers 28 of the gate structures 20 are exposed. Subsequently, a selective etching process is carried out to remove the cap layers 28, the insulating layers 26 and the gate conductive layers 24 of the gate structures 20, thereby forming a plurality of gate trenches located between the spacers 29. The gate dielectric layers 22 may either remain at the bottoms of the gate trenches or be removed to expose the top surface of the active region 160. Subsequently, a gate dielectric layer, a work function metal layer, a low-resistance metal layer, and a cap layer are sequentially formed, fully covering the dielectric layer 54 and filling the gate trenches. A chemical mechanical polishing process is performed to remove these material layers outside the gate trenches, thereby obtaining the metal gate structures 60 respectively in the gate trenches. The material of the contact etching stop layer 52 may include silicon dioxide (SiO₂), silicon nitride (SiN), silicon oxynitride (SiON), silicon carbonitride (SiCN), or a combination thereof. The material of the dielectric layer 54 may include silicon dioxide (SiO₂), but is not limited thereto. Each of the metal gate structures 60 includes a metal gate stack and the spacer 29 disposed on the sidewall of the metal gate stack, wherein the metal gate stack may include, from bottom to top, a gate dielectric layer 62, a work function metal layer 64, a low-resistance metal layer 66, and a cap layer 68. The material of the gate dielectric layer 62 includes silicon dioxide (SiO₂) and/or a high-k dielectric material such as hafnium oxide (HfO), hafnium silicate (HfSiO), hafnium silicon oxynitride (HfSiON), aluminum oxide (AlO), lanthanum oxide (LaO), lanthanum aluminum oxide (LaAlO), tantalum oxide (TaO), zirconium oxide (ZrO), zirconium silicate (ZrSiO), or hafnium zirconium oxide (HfZrO), but is not limited thereto. The material of the work function metal layer 64 is selected based on the conductivity type of the channel regions of the semiconductor device. For example, when the channel regions are N-type, the work function metal layer 64 may include titanium aluminum (TiAl), zirconium aluminum (ZrAl), tungsten aluminum (WAl), tantalum aluminum (TaAl), or hafnium aluminum (HfAl), but is not limited thereto. When the channel regions are P-type, the work function metal layer 64 may include titanium nitride (TiN), tantalum nitride (TaN), titanium carbide (TiC), tantalum carbide (TaC), tungsten carbide (WC), or titanium aluminum nitride (TiAlN), but is not limited thereto. The material of low-resistance metal layer 66 may include aluminum (Al), titanium (Ti), tantalum (Ta), tungsten (W), niobium (Nb), molybdenum (Mo), copper (Cu), titanium nitride (TiN), titanium carbide (TiC), tantalum nitride (TaN), titanium tungsten (Ti/W), or titanium/titanium nitride (Ti/TiN), but is not limited thereto. The material of the cap layer 68 may include silicon nitride (SiN), but is not limited thereto.

In summary, the present invention provides an SOI semiconductor device and a method for forming the same, which utilizes the selective growth of the epitaxial layer to create an air gap between the bottom surface of the epitaxial layer (the source/drain region) and the intermediate insulating layer of the SOI substrate, so that the off capacitance (C_{off}) of the semiconductor device may be significantly reduced, thereby enhancing the overall performance of the device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate comprising an insulating layer and a device layer disposed on the insulating layer, wherein the device layer comprises an active region;
a plurality of gate structures arranged parallel to each other on the active region;
a recess in the active region located between adjacent two of the gate structures and penetrating through the device layer;
an epitaxial layer in the recess; and
an air gap between a bottom surface of the epitaxial layer and a top surface of the insulating layer.

2. The semiconductor device according to claim 1, wherein the substrate is partially depleted silicon-on-insulator (PDSOI) substrate or a full depleted silicon-on-insulator (FDSOI) substrate.

3. The semiconductor device according to claim 1, wherein a thickness of the device layer ranges from 500 Å to 1450 Å.

4. The semiconductor device according to claim 1, wherein in a top view, the recess extends along a direction parallel to the gate structures.

5. The semiconductor device according to claim 1, wherein in a top view, the air gap extends along a direction parallel to the gate structures.

6. The semiconductor device according to claim 1, wherein the air gap has a diamond cross-sectional shape.

7. The semiconductor device according to claim 1, wherein a sidewall of the recess and the top surface of the insulating layer form an angle between 120 degrees and 130 degrees.

8. The semiconductor device according to claim 1, wherein the air gap has a triangular cross-sectional shape.

9. The semiconductor device according to claim 1, wherein a height of the air gap is between 20% and 25% of a thickness of the device layer.

10. The semiconductor device according to claim 1, further comprising an isolation structure formed in the device layer and surrounding the active region, wherein a bottom surface of the isolation structure is aligned with a bottom surface of the air gap along the top surface of the insulating layer.

11. A method for forming a semiconductor device, comprising:
providing a substrate comprising an insulating layer and a device layer disposed on the insulating layer, wherein the device layer comprises an active region;
forming a plurality of gate structures parallel to each other on the active region;
forming a recess in the active region and between adjacent two of the gate structures, wherein the recess penetrates through the device layer, exposing a top surface of the insulating layer; and
forming an epitaxial layer in the recess and an air gap between a bottom surface of the epitaxial layer and a top surface of the insulating layer.

12. The method for forming a semiconductor device according to claim 11, wherein the substrate is partially depleted silicon-on-insulator (PDSOI) substrate or a full depleted silicon-on-insulator (FDSOI) substrate.

13. The method for forming a semiconductor device according to claim 11, wherein a thickness of the device layer ranges from 500 Å to 1450 Å.

14. The method for forming a semiconductor device according to claim 11, wherein in a top view, the recess extends along a direction parallel to the gate structures.

15. The method for forming a semiconductor device according to claim 11, wherein in a top view, the air gap extends along a direction parallel to the gate structures.

16. The method for forming a semiconductor device according to claim 11, wherein the step of forming the recess comprises:
performing a dry etching process to form a U-shaped recess in the device layer; and
performing a wet etching process to expand the U-shaped recess into a diamond-shaped recess and exposing the top surface of the insulating layer.

17. The method for forming a semiconductor device according to claim 11, wherein a sidewall of the recess and the top surface of the insulating layer form an angle between 120 degrees and 130 degrees.

18. The method for forming a semiconductor device according to claim 11, wherein the air gap has a triangular cross-sectional shape.

19. The method for forming a semiconductor device according to claim 11, wherein a height of the air gap is between 20% and 25% of a thickness of the device layer.

20. The method for forming a semiconductor device according to claim 11, further comprising:
forming an isolation structure in the device layer to define the active region in the device layer, wherein a bottom surface of the isolation structure is aligned with a bottom surface of the air gap along the top surface of the insulating layer.
